(19) United States
(12) Patent Application Publication
(10) Pub. No.: US 2002/0089043 A1
(43) Pub. Date: Jul. 11, 2002

(54) SEMICONDUCTOR PACKAGE WITH SHORTENED ELECTRIC SIGNAL PATHS

(76) Inventors: SANG WOOK PARK, KYOUNGKI-DO (KR); MIN HUH, KYOUNGSANGBUK-DO (KR)

Correspondence Address: FINNEGAN, HENDERSON, FARABOW, GARRETT &, DUNNER LLP, 1300 I STREET, NW, WASHINGTON, DC, 20005, US

(21) Appl. No.: 09/473,004

(22) Filed: Dec. 28, 1999

(30) Foreign Application Priority Data
Dec. 29, 1998 (KR) 98-59972

(51) Int. Cl. H01L 21/44; H01L 23/48; H01L 29/40

(52) U.S. Cl. 257/668; 438/123; 257/692; 257/696; 257/702; 438/125; 257/737; 438/613; 257/787; 438/124

(57) ABSTRACT

Disclosed is a semiconductor package and method of fabricating the same. According to the package of the present invention, a semiconductor chip 20 is disposed such that its bonding pad 21 is disposed upwardly. Metal lines 30,31 are deposited along a surface, both sides and a bottom face of the semiconductor chip 20 thereby electrically connecting its upper end 30 to the bonding pad 21 of the semiconductor chip 20. An entire resultant is encapsulated with molding compounds 50,51 such that a lower end of the metal line 31 is exposed thereby forming a ball land. A solder ball 60 is mounted on a portion of the metal line 31 exposed from the molding compound 51.

### BACKGROUND OF THE INVENTION

1. Field of the Invention

This invention relates to a semiconductor package and method of fabricating the same.

2. Description of the Related Art

Studies on the chip size package, one of various semiconductor package types are continuously increased according to a tendency to minimize and lighten the package size, since the chip size package has an advantage that size of a chip can be set by the size of package. The chip size package is formed by using a non-flexible rigid substrate or by using a pattern tape.

In the method using a non-flexible rigid substrate, it is very difficult to produce a substrate. Instead, the method using a pattern tape is often suggested recently. With reference to FIG. 1, a conventional chip size package formed by the method using a pattern tape will be discussed.

As described in the drawing, a pattern tape 1 has a structure in which, from lower position, a solder resist 1a, a metal line 1b, an adhesive 1c and an elastomer id are successively stacked. A semiconductor chip 2 is attached on the elastomer 1d. A bonding pad 2a of the semiconductor chip 2 is electrically connected to the metal line 1b of the pattern tape 1 with a Cu ribbon 3. In the meantime, there is formed a ball land at the solder resist 1a and an entire resultant is encapsulated with molding compound 4 such that the ball land and a surface of the semiconductor chip 2 are exposed therefrom. A solder ball 5 to be mounted on a substrate, is formed at the exposed ball land.

However, the chip size package using the foregoing pattern tape has a drawback that the pattern tape is organized with complexity. A package shown in FIG. 2 has been suggested in this regard.

As shown in the drawing, an insulating layer 11 having a metal wiring layer is attached at bottom face of a semiconductor chip 10, and a solder ball 12 is directly mounted on a bottom face of the insulating layer 11.

However, the chip size package as shown in FIG. 1 has following drawbacks.

First of all, since the pattern tape is organized with four layers as above-mentioned description, the structure of pattern tape is very complicated and also fabricating process thereof is complicated. Furthermore, the pattern tape is very expensive and its inherent characteristic of intensity is weak.

Also the pattern tape and the bonding pad of the semiconductor chip are attached with the Cu ribbon, and the Cu ribbon is frequently disconnected while processing under high temperature. If an epoxy based molding compound is used for waterproof purpose, disconnection of the Cu ribbon is even more serious.

Meanwhile, a package shown in FIG. 2 does not use the pattern tape thereby simplifying its structure and shortening electrical connection path. However, there are also drawbacks as follows.

Since both sides of the semiconductor chip are exposed, the package has a weakness to the penetration of alien substances or an external mechanical impact.

Further, the adhesion property of soldering is entirely dependent upon the solder ball since the solder ball is attached directly to the insulating layer. Accordingly, so as to increase the adhesion property of the solder ball, it is required to increase size of the solder ball, in other words, total thickness of the semiconductor package is increased. Also, the solder ball supported by a jig is frequently damaged during an electricity test for the package, and the solder ball should be made of copper which is very expensive so as to prevent the damage.

### SUMMARY OF THE INVENTION

Therefore, the present invention is directed to solve the foregoing problems.

It is one object of the present invention to provide a semiconductor package having not complicated structure and capable of intensifying the penetration of alien substances or a mechanical intensity, and the method for fabricating the same.

It is another object of the present invention to shorten the electric signal transmission path thereby improving its electric characteristics.

It is still another object of the present invention to intensify the junction intensity of solder balls thereby preventing the solder balls from damaging during various tests.

To accomplish the foregoing objects, the package according to the present invention comprises as follows.

A semiconductor chip is disposed such that its bonding pad is disposed upwardly. A metal line is deposited along a surface, both sides and a bottom face of the semiconductor chip thereby electrically connecting its upper end to the bonding pad of the semiconductor chip. An entire resultant is encapsulated with a molding compound such that only a lower end of the metal line is exposed. A solder ball is mounted on the lower end of the metal line exposed from the molding compound.

In another aspect, an upper portion of the entire resultant is encapsulated with the molding compound so as to expose the bottom face of the semiconductor chip and the lower end of the metal line. An insulating layer is formed at the bottom face of the semiconductor chip except at the lower end of the metal line. A lower metal line whose one end is connected to the lower end of the metal line, is deposited at the insulating layer. A lower portion of the entire resultant is encapsulated with a lower molding compound so as to expose a selected portion of the lower metal line. The solder ball is mounted at the portion of the lower metal line exposed from the lower molding compound.

Meanwhile, if the upper and lower metal lines have a single-layered structure made of a material selected from a group consisting of Al, Cu, Ni, Cr, Ti, Au, Pt, Pd, Pb and Sn, there is formed a chemical compound by the reaction of metal lines and solder balls, which may degrade the junction reliability. To prevent aforementioned problem, it is preferable to form an under bump metallurgy(UBM) at a portion of the metal line exposed from the lower molding compound, i.e. at the ball land.

The UBM may have said single-layered structure made of a selected material as used for the metal line or have a multi-layered structure selected from a group consisting of Cu/Ni/Au, Cu/Ni/Au/Cr, Cu/Ni/Au/Co, Cu/Ni/Au/Sn, Cu/Ni/Au/Cr/Sn, Cu/Ni/Au/Co/Sn or Cu/Ni/Pb. In the meantime, if the metal line has the multi-layed structure made of the same material as in the multi-layered UBM, no additional UBM is required.

The package as described above is fabricated according to following steps.

A trench is formed by etching a portion between each semiconductor chip constituted in a wafer. At this time, each bonding pad of the semiconductor chip is located close to both sides of the trench. A metal line is deposited at an inner wall of the trench and on the bonding pad, and then an insulating layer is formed on an entire resultant. As for the material used in the insulating layer, a nitride layer, an oxide layer or a polymeric material can be used. A molding compound is coated on the insulating layer.

Continuously, by polishing, a bottom face of the wafer is removed by a selected thickness to expose a bottom of the trench. An insulating layer is formed at the entire bottom face of the wafer. And then, the insulating layer is removed by etching a selected portion to expose metal lines. Another metal line which is electrically connected to a lower end of the exposed metal line, is deposited on the insulating layer. Another molding compound is coated at a bottom face of the entire resultant and a selected portion of the another molding compound is etched until the metal line deposited on the insulating layer is exposed thereby forming a ball land. An UBM is formed at the exposed ball land and a solder ball is mounted on the UBM. Finally, the wafer is separated into individual semiconductor chips by sawing along the trenches.

According to the construction of the present invention, since the metal line is deposited along the surface, both sides and the bottom face of the semiconductor chip and this metal line becomes the electric signal transmission path, the electric signal transmission path is shortened thereby improving the electrical characteristics. Further, the metal line can be deposited thinly, therefore total thickness of the package is also reduced.

### BRIEF DESCRIPTION OF THE DRAWINGS

FIGS. 1 and 2 are cross-sectional views showing a conventional package.

FIG. 3 is a drawing for showing a package according to the present invention.

FIGS. 4 to 15 illustrate a process of fabricating a package according to a first embodiment of the present invention.

FIG. 16 is a drawing for showing a package of stack type according to a second embodiment of the present invention.

FIGS. 17 to 18 are drawings for showing a package of stack type according to a third embodiment of the present invention.

FIGS. 19 to 20 illustrates a process of fabricating a package according to a fourth embodiment of the present invention.

FIG. 21 is a drawing for showing a multi-chip package according to a fifth embodiment of the present invention.

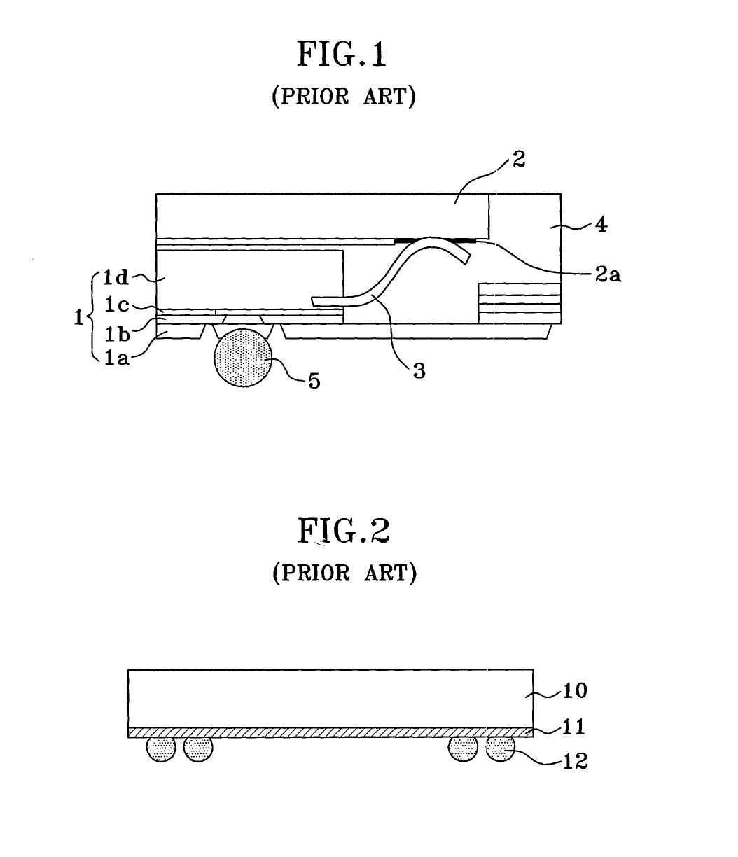

### DETAILED DESCRIPTION OF THE PREFERRED EMBODIMENTS

[First Embodiment]

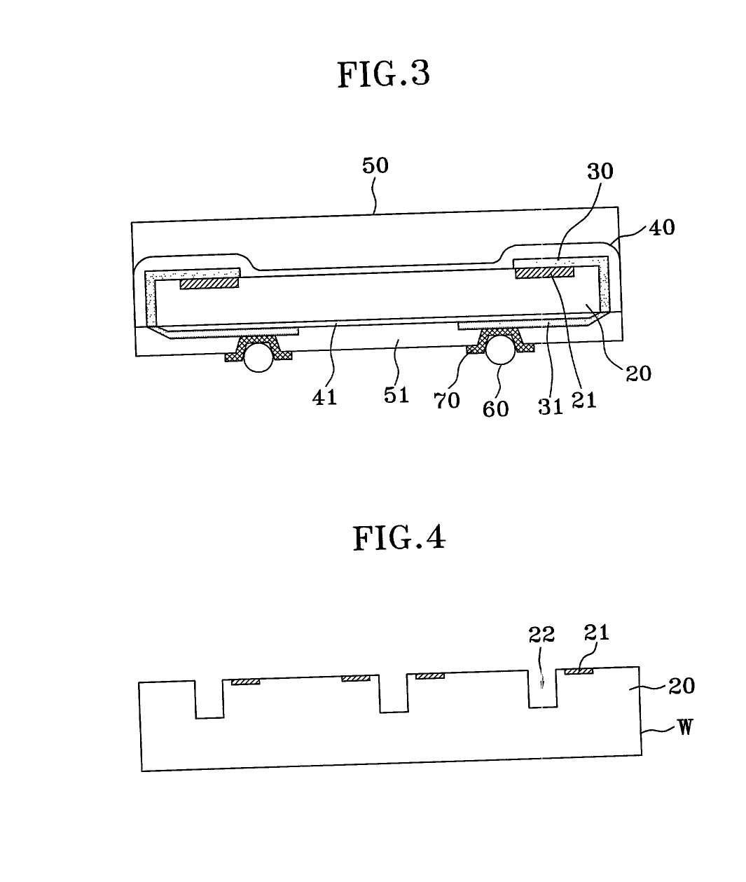

As shown in FIG. 3, a semiconductor chip 20 is disposed such that its bonding pad 21 is disposed upwardly. An upper metal line 30 is deposited at both ends of a surface and at both sides of the semiconductor chip 20, thereby electrically connecting the upper metal line 30 to the bonding pad 21. To insulate the upper metal line 30, there is formed an upper insulating layer 40 over and at a side of an entire resultant. Accordingly, a lower end of the metal line 30 which extends though between the upper insulating layer 40 and both sides of the semiconductor chip 20, is exposed to a lower position. An upper molding compound 50 is coated over the upper insulating layer 40.

A lower insulating layer 41 is formed at a bottom face of the semiconductor chip 20. Therefore, the lower end of the upper metal line 30 is still exposed. A lower metal line 31 which is electrically connected to the exposed upper metal line 30, is deposited at a selected portion of the lower insulating layer 41. A lower molding compound 51 is coated at a lower portion of the entire resultant such that the lower metal line 31 is exposed. A region in which the lower metal line 31 is exposed, is a ball land and a solder ball 60 is mounted on the ball land.

In the meantime, the upper and lower metal lines 30,31 have a single-layered structure made of a material selected from a group consisting of Al, Cu, Ni, Cr, Ti, Au, Pt, Pd, Pb and Sn, or have a multi-layered structure having a plurality of layers stacked therein.

However, if the lower metal line 31 and the solder ball 60 is contacted each other, certain metal atoms in the lower metal line 31 is diffused into the solder ball 60 made of Pb-Sn and a chemical compound may formed at an interface thereof. The compound of those metals may weaken junction property between the lower metal line 31 and the solder ball. Therefore, it is preferable to formed an UBM 70 at the ball land.

The UBM 70 may have said single-layered structure made of a selected material as used for the metal lines 30,31 or have a multi-layered structure selected from a group consisting of Cu/Ni/Au, Cu/Ni/Au/Cr, Cu/Ni/Au/Co, Cu/Ni/Au/Sn, Cu/Ni/Au/Cr/Sn, Cu/Ni/Au/Co/Sn or Cu/Ni/Pb. In the meantime, if the metal lines 30,31 have the multi-layed structure made of the same material as in the multi-layered UBM, the additional UBM 70 is not required since the metal lines 30,31 themselves function to prevent the diffusion.

Hereinafter, a method for fabricating a package having aforementioned constructions will be discussed in detail.

As shown in FIG. 4, a plurality of semiconductor chips 20 are constituted in a wafer W and divided along scribe lines formed on the wafer W. The bonding pad 21 of the semiconductor chip 20 is disposed on the wafer W. Under the present circumstance, each portion of the scribe line is etched with a depth of 8˜12 μm thereby forming a trench 22.

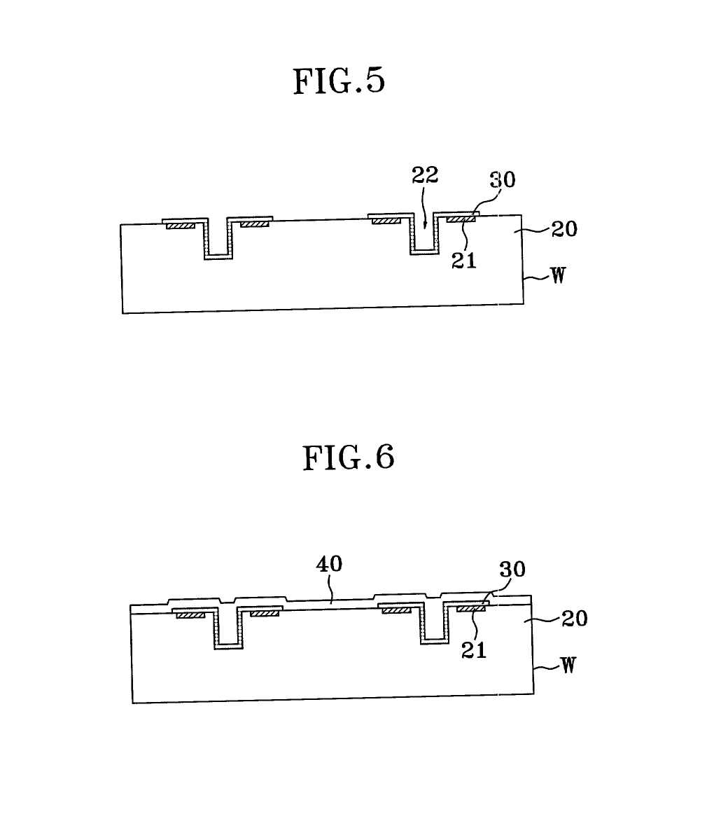

Continuously, as shown in FIG. 5, the upper metal line 30 is deposited over the entire surface of the semiconductor chip 20 and at inner walls of the trench 22 by those method of PVD, CVD or electroplating. Herein, a width of the upper metal line 30 is 10˜1,000 μm and its thickness is 0.5˜5 μm. A portion of the upper metal line 30 deposited on a portion between the bonding pads 21 of the semiconductor chip 20 is etched and removed. Accordingly, the upper metal line 30 is remained only at the inner wall of the trench 20 and on two bonding pads 21 which are disposed close to both ends of the trench 22.

Afterward, the upper insulating layer 40 is formed over the entire resultant so as to electrically insulate the upper metal line 30. As a material to be used for the upper insulating layer 40, a nitride layer or an oxide layer can be selected and/or a polymeric material can be used also for stress-releasing purpose.

And then, the entire upper portion of the wafer W is encapsulated with the upper molding compound 50 to insulate the wafer W and to absorb external impact and to prevent infiltration of moisture. There are two methods for encapsulating.

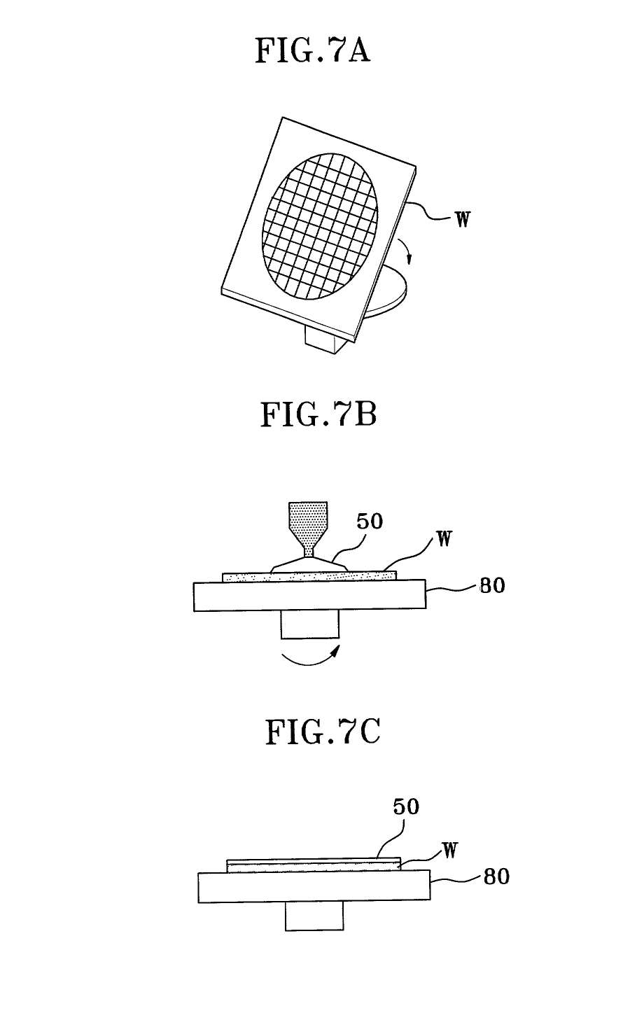

First, as shown in FIG. 7A, the wafer W is located at a rotating plate 80. With rotating the rotating plate 80 as shown in FIG. 7B, the upper molding compound 50 is spin-coated on the wafer W thereby forming the upper molding compound 50 over the entire upper portion of the wafer W.

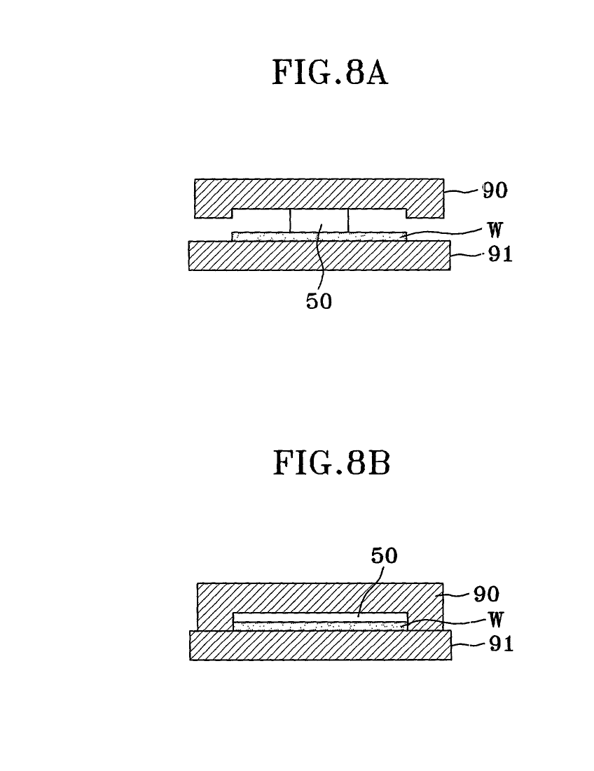

In another aspect, as shown in FIG. 8A, the wafer W is disposed on a lower die 91, and the upper molding compound 50, not resin type, is positioned at the wafer W. And then, the upper molding compound 50 is pressed to an upper die 90 as shown in FIG. 8B.

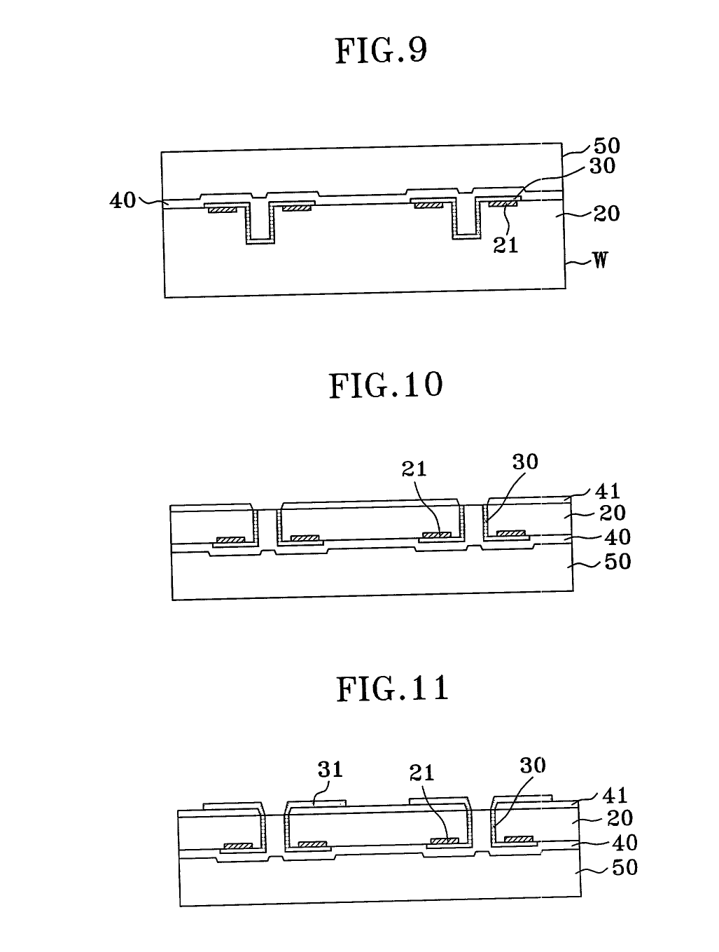

A structure formed by taking one method between the above two methods, is shown in FIG. 9. Next, the wafer W is reversed as shown in FIG. 10 so that the upper molding compound 50 is turned toward a lower portion. And, a selected thickness of a surface of the wafer W is removed by a chemical-mechanical polishing until the trench 22 is exposed. Then, a lower end of the upper metal line 30 is exposed through the wafer W. Successively, the lower insulating layer 41 is formed on the wafer W. Afterward, a relevant portion of the lower insulating layer 41 is etched and removed so as to expose the upper insulating layer 40 and the upper metal line 30 which are buried in the trench 22.

As shown in FIG. 11, the lower metal line 31 is deposited on the entire resultant and a relevant portion of the lower metal line 31 is etched and removed so as to expose the trench region 22 and a central portion of the semiconductor chip 20. By doing so, one end of the lower metal line 31 as a pattern having a form of line is connected to the upper metal line 30.

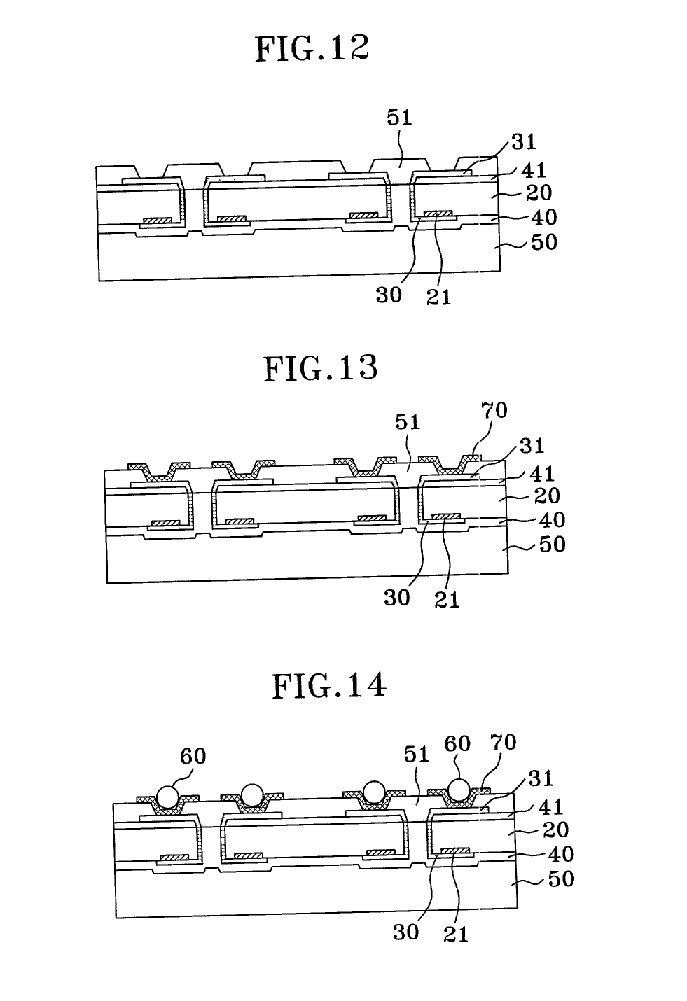

Next, as shown in FIG. 12, the lower molding compound 51 is coated over the entire resultant, and a relevant portion of the lower molding compound 51 is etched so as to expose a portion of the lower metal line 31 deposited on the lower insulating layer 41. According to foregoing process, a ball land 61 exposing the lower metal line 31 is formed.

And then, as shown in FIG. 13, the UBM 70 is deposited at the ball land 61. Herein, if the lower metal line 31 has said multi-layered structure, the step of forming the UBM 70 can be omitted.

Furthermore, as shown in FIG. 14, the solder ball 60 is mounted on the UBM 70. In the method for fabricating package according to the present invention, the step of mounting the solder ball 60 is performed above all under a wafer phase.

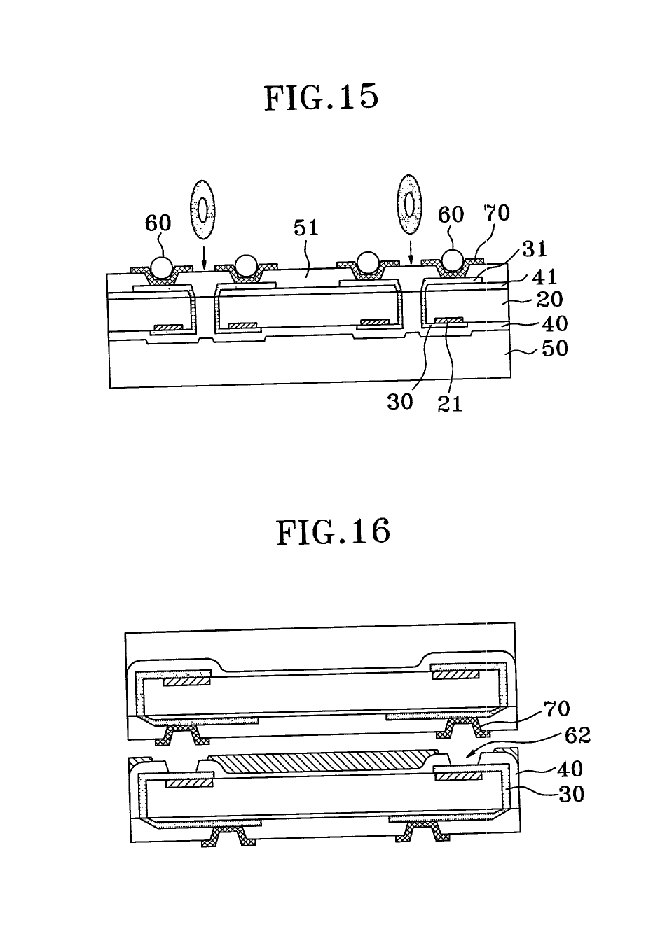

Finally, as shown in FIG. 15, the wafer W is separated into individual chips 20 by sawing the trench portion, thereby completing a package according to the first embodiment as shown in FIG. 3.

Meanwhile, the metal line, the insulating layer and the molding compound have upper and lower portions in the first embodiment, however it is not necessary. In other words, the upper and lower metal lines as shown in FIG. 3 can be formed as one line, and also the entire resultant can be encapsulated with one molding compound where no insulating layer is formed.

[Second Embodiment]

FIG. 16 illustrates the package as suggested in the first embodiment by stacking the package according to the second embodiment of the present invention.

As shown in the drawings, a package as shown in FIG. 3 is stacked up and down. So as to expose the upper metal line 30 deposited on the bonding pad 21, a via hole 62 is formed by etching relevant portions of the upper insulating layer 40 and the upper molding compound 50. An UBM 70 of another package disposed in the upper position, is disposed over the via hole 62 and then the UBM 70 and the exposed upper metal line 30 are electrically connected by a solder ball or a conductive bump thereby accomplishing a stack package.

[Third Embodiment]

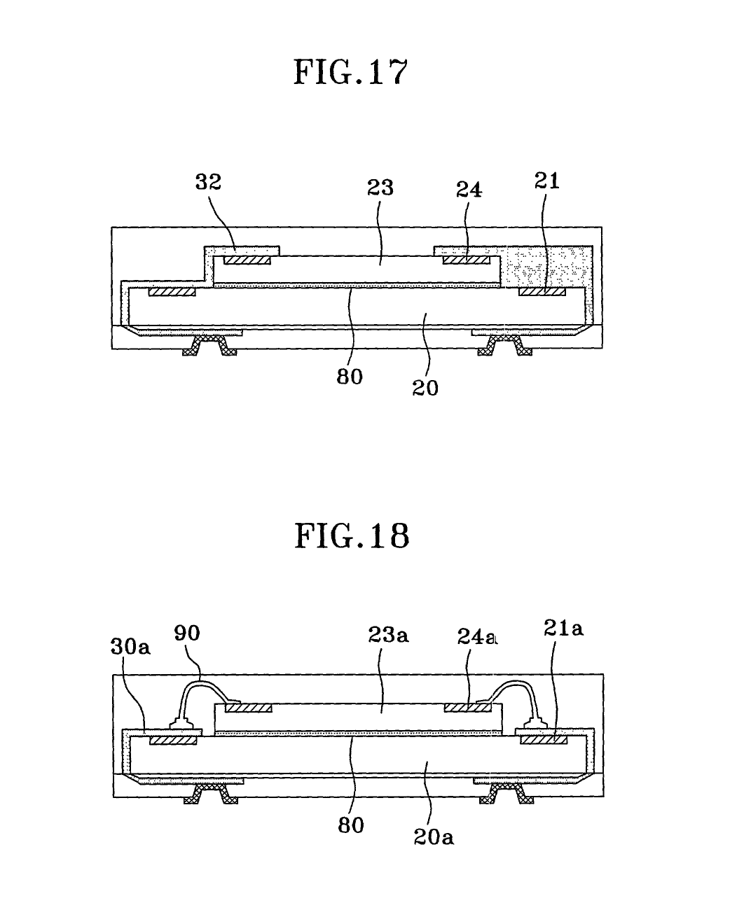

FIGS. 17 and 18 illustrate a stack package according to the third embodiment of the present invention. An upper metal line 32 is used in the stack package shown in FIG. 17 and a metal wire 90 is used in the stack package shown in FIG. 18.

First of all, as shown in FIG. 17, an upper semiconductor chip 23 having a shorter width than the semiconductor chip 20 shown in FIG. 3, is attached to a surface of the lower semiconductor chip 20 by the medium of an adhesive 80 such that a bonding pad 24 of the upper semiconductor chip 23 is disposed upwardly. Especially, the upper semiconductor chip 23 has a width capable of exposing the bonding pad 21 of the lower semiconductor chip 20. An upper metal line 32 is deposited not only on the bonding pad 21 of the lower semiconductor chip 20 but at both sidewalls of the upper semiconductor chip 23 and on the bonding pad 24 of the same. Consequently, the bonding pads 21,24 of the respective semiconductor chips 20,23 are electrically connected each other by the upper metal line 32.

In the mean time, a limitation in the making of the package as shown in FIG. 17, is that the stacked semiconductor chips 20,23 should have thinner thickness capable of metal-depositing.

Accordingly, as shown in FIG. 18, if thickness of stacked semiconductor chips 20a,23a are too thick to deposit so that metal may not be deposited, the upper metal line 30 is used together with a metal wire 90. Namely, the upper metal line 30 is formed with the same constitution as in FIG. 3, and instead, a bonding pad 24a of the upper semiconductor chip 30 is electrically connected to the upper metal line 30 by the medium of the metal wire 90 thereby accomplishing a stack package.

[Fourth Embodiment]

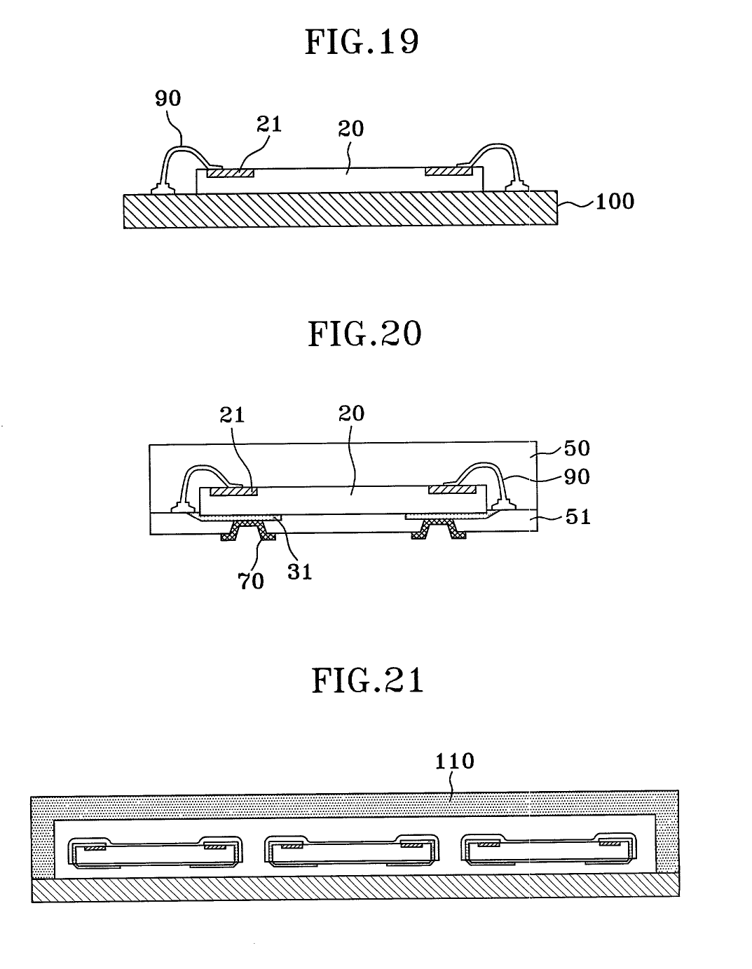

FIGS. 19 and 20 are drawings for showing a package according to the fourth embodiment of the present invention.

As shown in FIG. 19, the semiconductor chip 20 is disposed over a dummy frame 100 such that the bonding pad 21 of the semiconductor chip 20 is disposed upwardly, and the bonding pad 21 and the dummy frame 100 are connected by a metal wire 90. In other words, the upper metal line used in the first embodiment is not used in the present embodiment 4.

Afterward, the upper molding compound 50 encapsulates an upper portion of an entire resultant and the dummy frame 100 is removed. And then, a lower end of the metal wire 90 is exposed from the upper molding compound 50. So as to electrically connect to the exposed portion of the metal wire 90, the lower metal line 31 is deposited at a bottom face of the semiconductor chip 20. Next, the lower molding compound 51 encapsulates a lower portion of the entire resultant such that the lower metal line 31 is exposed. The UBM 70 is deposited at the portion of the lower metal line 31 exposed from the lower molding compound 51, i.e. the ball land, and the solder ball(not shown) is mounted on the UBM 70 thereby accomplishing a package as shown in FIG. 20.

Comparing the first embodiment to the fourth embodiment, the metal wire is used in the fourth embodiment instead of the upper metal line, and no lower insulating layer is used since thickness of the semiconductor chip of the fourth embodiment is thicker than that of the first embodiment.

[Fifth Embodiment]

FIG. 21 illustrates a package, more particularly a multi-chip package according to the fifth embodiment of the present invention.

As shown in the drawing, packages shown in FIG. 3 of the first embodiment which are not encapsulated with molding compound, are disposed within a ceramic capsule 110. The ceramic capsule 110 is directly installed on a substrate, a solder ball is used generally.

As disclosed in the above specification, since the electric signal transmission path, i.e. from the bonding pad to the solder ball is formed by the metal line capable of shortening the path, not by the metal wire, the electric signal transmission path can be shortened and then electric characteristics of a package can be improved.

Further, the thickness of the package can be reduced since the metal line is very thin.

Especially, since after all the semiconductor chips are packaged and the solder ball is mounted, and then the wafer is separated into individual semiconductor chips, the entire fabricating process may perform under the wafer condition thereby obtaining simpler packaging process.

Although preferred embodiments of the package are described and illustrated, various other modifications will be apparent to and can be readily made by those skilled in the art without departing from the scope and spirit of the present invention.

What is claimed is,

1. A semiconductor package comprising:
a semiconductor chip whose bonding pad is disposed upwardly;
a metal line deposited at the bonding pad, both sidewalls and a bottom face of said semiconductor chip;
a molding compound for encapsulating an entire resultant such that a ball land is formed to expose the metal line portion deposited at the bottom face of the semiconductor chip; and
a solder ball mounted on the ball land.

2. The semiconductor package of claim 1, wherein the metal line is divided into an upper metal line deposited at the bonding pad and the both sidewalls of the semiconductor chip, and a lower metal line connected to the upper metal lane and deposited at the bottom face of the semiconductor chip.

3. The semiconductor package of claim 2, wherein an upper insulating layer is sandwiched between the upper metal line and the molding compound, and a lower insulating layer is sandwiched between the lower metal line and the bottom face of the semiconductor chip.

4. The semiconductor package of claim 3, wherein the molding compound is divided into an upper molding compound in the upper portion of the semiconductor chip and a lower molding compound in the lower portion of the semiconductor chip.

5. The semiconductor package of claim 1, wherein the metal line has a multi-layered structure comprising a single layer or over two layers made of a material selected from a group consisting of Al, Cu, Ni, Cr, Ti, Au, Pt, Pd, Pb, Sn.

6. The semiconductor package of claim 1, wherein an under bump metallurgy is formed at the ball land.

7. The semiconductor package of claim 6, wherein the under bump metallurgy is selected from a group consisting of Cu/Ni/Au, Cu/Ni/Au/Cr, Cu/Ni/Au/Co, Cu/Ni/Au/Sn, Cu/Ni/Au/Cr/Sn, Cu/Ni/Au/Co/Sn or Cu/Ni/Pb.

8. The semiconductor package of claim 1, wherein a via hole is formed by etching a selected portion of the molding compound so as to expose the metal line portion deposited on the bonding pad of the semiconductor chip, and the semiconductor package is constructed as a stack type by electrically connecting the metal line portion exposed through the via hole and a solder ball of another package.

9. A semiconductor package comprising:
an upper semiconductor chip whose bonding pad is disposed upwardly;
a lower semiconductor chip disposed at a bottom face of the upper semiconductor chip, wherein the lower semiconductor chip has a bonding pad exposed from the upper semiconductor chip and disposed upwardly;
an upper metal line extended from the bonding pad of the upper semiconductor chip to both sidewalls of the lower semiconductor chip thereby electrically connecting the respective bonding pads of the upper and lower semiconductor chips;
an upper molding compound for encapsulating an entire resultant such that a lower end of the upper metal line and a bottom face of the semiconductor chip are exposed therefrom;
an insulating layer formed at the bottom face of the semiconductor chip;
a lower metal line deposited at the insulating layer, wherein one end of the lower metal line is electrically connected to the lower end of the upper metal line;
a lower molding compound for encapsulating the entire resultant such that a selected portion of the lower metal lines is exposed therefrom;
an under bump metallurgy formed at the portion of the lower metal line exposed from the lower molding compound; and
a solder ball mounted on the under bump metallurgy.

10. A semiconductor package comprising:
an upper semiconductor chip whose bonding pad is disposed upwardly;
a lower semiconductor chip disposed at a bottom face of the upper semiconductor chip, wherein the lower semiconductor chips has a bonding pad exposed from the upper semiconductor chip and disposed upwardly;
an upper metal line deposited at the bonding pad of the lower semiconductor chip and at both sidewalls;
a metal wire for electrically connecting the upper metal line and the bonding pad of the upper semiconductor chip;
an upper molding compound for encapsulating an entire resultant such that a lower end of the upper metal line and a bottom face of the semiconductor chip are exposed therefrom;
an insulating layer formed at the bottom face of the semiconductor chip;
a lower metal line deposited at the insulating layer, wherein one end of the lower metal line is electrically connected to the lower end of the upper metal line;
a lower molding compound for encapsulating the entire resultant such that a selected portion of the lower metal lines is exposed therefrom;
an under bump metallurgy formed at the portion of the lower metal line exposed from the lower molding compound; and
a solder ball mounted on the under bump metallurgy.

11. A semiconductor package comprising:
a semiconductor chip whose bonding pad is disposed upwardly;
a metal wire whose one end is electrically connected to the bonding pad of the semiconductor chip;
a metal line deposited at a bottom face of the semiconductor chip and whose one end is electrically connected to the metal wire;
a molding compound for encapsulating an entire resultant such that the metal line is exposed therefrom thereby forming a ball land; and
a solder ball mounted on the ball land.

12. A method for fabricating a semiconductor package comprising the steps of:
forming a trench at each portion between semiconductor chips constitute in a wafer;
depositing an upper metal line at an inner wall of the trench and on a bonding pad of the semiconductor chip;
encapsulating an upper portion of an entire resultant with the upper molding compound;
removing the wafer by a selected thickness by polishing so that a bottom face of the trench and the upper metal line are exposed;
electrically connecting the upper metal line and a lower metal line by depositing the lower metal line at a selected portion in a bottom face of the semiconductor chip;
encapsulating lower portion of an entire resultant with a lower molding compound so that a ball land to which the lower metal line is exposed, is formed;
mounting a solder ball on the ball land; and
separating the wafer into individual semiconductor chips by sawing the wafer along the trench.

13. The method of claim 12, further comprising a step of forming an under bump metallurgy at the ball land.
